(19) United States
(12) Patent Application Publication
(10) Pub. No.: US 2025/0359089 A1
(43) Pub. Date: Nov. 20, 2025

(54) PILLAR WITH EMBEDDED CAPACITOR

(71) Applicant: QUALCOMM Incorporated, San Diego, CA (US)

(72) Inventors: No Name Given SURAJ PRAKASH, San Diego, CA (US); John Jong-Hoon LEE, San Diego, CA (US); Sameer Sunil VADHAVKAR, San Diego, CA (US); Heun Gun SHIN, San Diego, CA (US); Francesco CARRARA, San Diego, CA (US); Antonino SCUDERI, San Diego, CA (US)

(21) Appl. No.: 18/668,585

(22) Filed: May 20, 2024

(51) Int. Cl. H03H 7/01

(52) U.S. Cl. CPC H10D 1/692; H03H 7/0115; H10D 1/20

(57) ABSTRACT

Various aspects of the present disclosure generally relate to wireless communication, and to a pillar that includes one or more structures configured to define a capacitor. For example, a device includes a die, a substrate, and a pillar having an embedded capacitor. The pillar is electrically connected to one or more conductors of the die and to one or more conductors of the substrate. The pillar includes a first conductive structure and a second conductive structure. The pillar also includes a dielectric layer disposed between the first conductive structure and the second conductive structure to define the embedded capacitor.

### FIELD

Various features relate to capacitor devices.

### DESCRIPTION OF RELATED ART

State-of-the-art mobile application devices demand a small form factor, low cost, a tight power budget, and high electrical performance. In many cases, there are conflicts among these various design goals. For example, the performance of some circuits can be improved by the inclusion of sufficient capacitance. However, including capacitors capable of providing this capacitance in an integrated circuit in a die can take up significant die area, resulting in an overall increase in the size and cost of the die. Including the capacitors in a substrate coupled to the die increases interconnect complexity and substrate cost.

### SUMMARY

Various features relate to integrated circuit devices.

One example provides a device that includes a die, a substrate, and a pillar having an embedded capacitor. The pillar is electrically connected to one or more conductors of the die and to one or more conductors of the substrate. The pillar includes a first conductive structure, a second conductive structure, and a dielectric layer disposed between the first conductive structure and the second conductive structure to define the embedded capacitor.

Another example provides a method of fabrication that includes forming a pillar electrically connected to one or more conductors of a die. The pillar includes a first conductive structure, a second conductive structure, and a dielectric layer disposed between the first conductive structure and the second conductive structure to define an embedded capacitor. The method also includes electrically connecting the die to one or more conductors of a substrate using the pillar.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1A illustrates a schematic cross-sectional profile view of an exemplary device that includes a pillar with an embedded capacitor.

FIG. 1B illustrates a schematic perspective view of the pillar with the embedded capacitor of FIG. 1A.

FIG. 1C illustrates a schematic bottom view of the pillar with the embedded capacitor of FIG. 1A.

FIG. 2A illustrates a schematic cross-sectional profile view of an exemplary pillar with multiple embedded capacitors.

FIG. 2B illustrates a schematic perspective view of the pillar with the multiple embedded capacitors of FIG. 2A.

FIG. 2C illustrates a schematic bottom view of the pillar with the multiple embedded capacitors of FIG. 2A.

FIG. 3A illustrates a schematic cross-sectional profile view of an exemplary pillar with multiple embedded capacitors.

FIG. 3B illustrates a schematic perspective view of the pillar with the multiple embedded capacitors of FIG. 3A.

FIG. 3C illustrates a schematic bottom view of the pillar with multiple embedded capacitors of FIG. 3A.

FIG. 4A illustrates a schematic cross-sectional profile view of an exemplary device that includes a pillar with an embedded capacitor.

FIG. 4B illustrates a schematic perspective view of the pillar with the embedded capacitor of FIG. 4A.

FIG. 5A illustrates a schematic cross-sectional profile view of an exemplary pillar with an embedded capacitor.

FIG. 5B illustrates a schematic bottom view of the pillar with the embedded capacitors of FIG. 5A.

FIG. 6A illustrates a schematic cross-sectional profile view of an exemplary pillar with multiple embedded capacitors.

FIG. 6B illustrates a schematic bottom view of the pillar with multiple embedded capacitors of FIG. 6A.

FIG. 7A illustrates a schematic cross-sectional profile view of an exemplary pillar with an embedded capacitor.

FIG. 7B illustrates a schematic perspective view of the pillar with the embedded capacitors of FIG. 7A.

FIG. 8A illustrates a diagram illustrating aspects of a circuit that includes an exemplary pillar with an embedded capacitor.

FIG. 8B illustrates a schematic circuit diagram equivalent to the diagram of FIG. 8A.

FIG. 9 illustrates an exemplary sequence for fabricating an exemplary pillar that includes an embedded capacitor.

FIG. 10A illustrates a first part of an exemplary sequence for fabricating an exemplary pillar that includes an embedded capacitor.

FIG. 10B illustrates a second part of an exemplary sequence for fabricating an exemplary pillar that includes an embedded capacitor.

FIG. 10C illustrates a third part of an exemplary sequence for fabricating an exemplary pillar that includes an embedded capacitor.

FIG. 11 illustrates an exemplary flow diagram of a method of fabrication of a device that includes an exemplary pillar that includes an embedded capacitor.

FIG. 12 illustrates a schematic diagram of an exemplary device that includes a pillar with an embedded capacitor.

FIG. 13 illustrates various electronic devices that may integrate an exemplary pillar with an embedded capacitor described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Integrated circuits can include capacitors to facilitate impedance matching, filtering (e.g., limiting passage of particular frequencies or blocking direct current signals), tuning, etc. As an example, in mobile data uses, capacitors can be included in matching networks. Such matching networks are generally designed to support impedance matching for a large bandwidth and a tight locus. Additionally, fixed (rather than tunable) matching networks may be preferable for some applications to reduce cost.

Various solutions have been used to provide such capacitors, including using surface mounted capacitors and/or building capacitors into semiconductor dies. Each of these approaches has downsides. For example, including capacitors in a semiconductor die increases fabrication costs of the die and increases die size. Additionally, if a capacitor on a die is to have both direct current and alternating current connections to a substrate, two different die/substrate interconnects are needed. Each of these concerns tends to increase device size and manufacturing cost.

Disclosed embodiments provide a pillar that includes an embedded capacitor. The pillar can be formed, for example, as a flip-chip pillar of a die and used to provide one or more electrical connections between circuitry of the die and the substrate. Thus, the pillar can be used to provide capacitance, avoiding (or reducing the number or size of) surface mounted or die based capacitors and enabling a reduction in size of the die, the substrate, or both.

Aspects of the present disclosure are directed to a pillar having an embedded capacitor that includes two or more conductive structures separated by dielectric layer(s). In some embodiments, the pillar can include two or more conductive paths, such as a direct current (DC) path (e.g., a path that bypasses the capacitor) and an alternating current (AC) path (e.g., a path through the capacitor). In one or more embodiments in which the pillar includes two or more conductive paths, the number of electrical interconnects between the die and substrate can be reduced as compared to a conventional device that includes separate pillars for each conductive path.

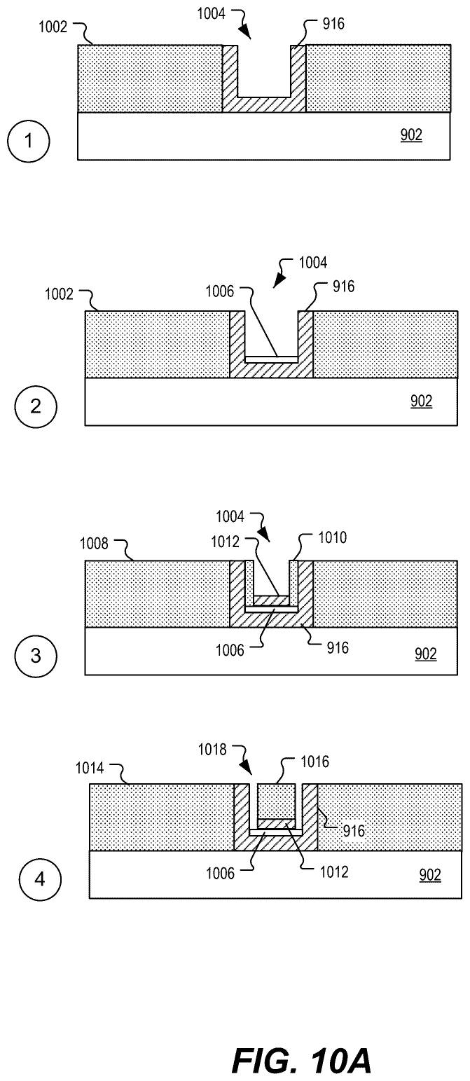

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 9, multiple locations are illustrated and associated with reference numbers 934A and 934B. When referring to a particular one of these locations, such as a location 934A, the distinguishing letter “A” is used. However, when referring to any arbitrary one of these locations or to these locations as a group, the reference number 934 is used without a distinguishing letter.

Exemplary Devices/Implementations Including a Pillar with an Embedded Capacitor

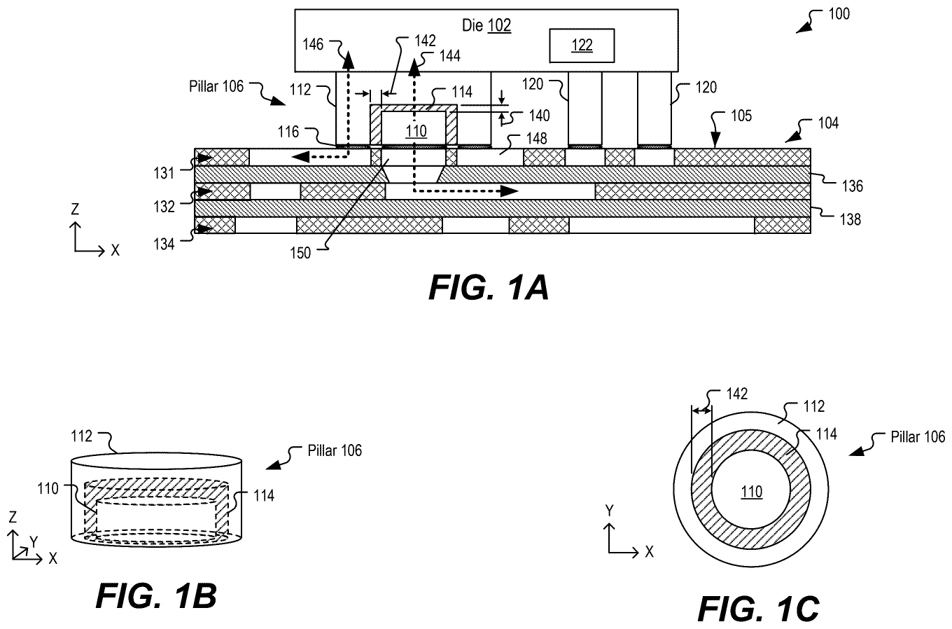

FIG. 1A illustrates a schematic cross-sectional profile view of an exemplary device 100 that includes a pillar 106 with an embedded capacitor. The device 100 also includes a die 102 and a substrate 104. The pillar 106 with the embedded capacitor is electrically coupled to one or more conductors of the die 102 and to one or more conductors of the substrate 104. FIG. 1B illustrates a schematic perspective view of the pillar 106, and FIG. 1C illustrates a schematic bottom view of the pillar 106.

The die 102 includes integrated circuitry 122, such as a plurality of transistors and/or other circuit elements arranged and interconnected to form logic cells, memory cells, amplifiers, or other circuitry blocks. For example, the integrated circuitry 122 can include a power amplifier, a low noise amplifier, a direct amplifier, or other circuit elements of a radio frequency front end. Components of the integrated circuitry 122 can be formed in and/or over a semiconductor substrate, such as silicon, germanium, gallium arsenide, indium phosphide, gallium nitride, etc. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry 122 in or over the semiconductor substrate.

Although FIG. 1A shows the die 102 as a single die, in some embodiments, the device 100 can include multiples, such as more than one of the die 102. For example, two or more dies can be arranged and interconnected as a three-dimensional (3D) IC device that is electrically connected to the substrate 104 using the pillar 106. Additionally, or alternatively, two or more dies can be arranged side-by-side on the substrate 104. It is noted that any of the conductive interconnects and contacts described herein can include, for example, microbumps, conductive pillars, conductive pads (e.g., for pad to pad bonding), or other similar chiplet-to-chiplet interconnect contacts used for 3D chiplet stacking.

In addition to the pillar 106, the device 100 can include one or more additional pillars 120 electrically connected to one or more conductors of the die 102 and to one or more conductors of the substrate 104. One or more of the additional pillars 120 can include conventional copper pillars. Alternatively, or additionally, one or more of the additional pillars 120 can include an embedded capacitor, similar to the pillar 106. In a particular aspect, the pillar 106 has the same height as each of the one or more additional pillars 120. For example, the pillar 106 has a first pillar height that is substantially equal to a second pillar height of each of the one or more additional pillars 120. The additional pillars 120 may electrically connect additional conductors of the die 102 to additional conductors of the substrate 104. In some implementations, the device 100 includes a plurality of additional pillars 120 electrically connecting additional conductors of the die 102 to additional conductors of the substrate 104.

The substrate 104 includes a plurality of metal layers interspersed with dielectric layers. For example, in FIG. 1A, the substrate 104 includes a metal layer 131, a metal layer 132, and a metal layer 134. In this example, the metal layer 131 is separated from the metal layer 132 by a dielectric layer 136, and the metal layer 132 is separated from the metal layer 134 by a dielectric layer 138. The metal layers 131-134 are selectively interconnected to one another by vias to define conductive paths that enable the die 102 to be electrically connected to other devices (e.g., other dies on the same substrate 104 or to off package devices). The metal layers 131-134 are patterned to define various individual conductors (e.g., traces) and/or, optionally, passive circuit elements, such as inductors. For example, a spiral coil of an inductor can be formed in one or more of the metal layers 131-134. As another example, two or more of the metal layers 131-134 can be interconnected in a manner that defines a solenoid coil.

In some implementations, the metal layer 131 may be configured as an inductor, such as a choke inductor. Additionally, or alternatively, the metal layer 132 may be configured as one or more inductors, such as a first inductor and a second inductor. In some such implementations, the integrated circuitry 122 can include a transistor electrically coupled to the pillar 106.

The pillar 106 includes two or more conductive structure separated from one another by one or more dielectric layers. For example, in FIGS. 1A-1C, the pillar 106 includes a conductive structure 110 (also referred to herein as a “first conductive structure 110”) and a conductive structure 112 (also referred to herein as a “second conductive structure 112”) separated from one another by a dielectric layer 114 (also referred to herein as a “first dielectric layer 114”). In some implementations, the conductive structure 110 is nested within the conductive structure 112. The conductive structures 110, 112 can include copper or another metal or metal alloy, and the dielectric layer(s) can include silicon nitride, silicon oxynitride, aluminum oxide, etc., as illustrative, non-limiting examples. In some implementations, the conductive structures 110, 112 include copper, and the dielectric layer(s) include silicon nitride. The conductive structures 110, 112 and the dielectric layer 114 together form a capacitor. For example, when a voltage differential exists between the conductive structure 110 and the conductive structure 112, energy can be stored in an electric field in the dielectric layer 114. Thus, the conductive structures 110, 112 can behave like plates of a capacitor providing a capacitively coupled path 144 (also referred to herein as a “capacitively coupled signal path 144” or an “AC path 144”) from the conductive structure 110 to the conductive structure 112, or vice versa.

The capacitively coupled path 144 between the conductive structures 110, 112 (e.g., through the capacitor) enables communication of AC signals between the die 102 and the substrate 104. However, DC signals are not communicated between the conductive structures 110, 112 through the capacitor. In some embodiments, the conductive structure 112 also provides a DC signal path 146 (also referred to as a “direct-current path” or “DC path”) between the die 102 and the substrate 104.

In FIG. 1, the pillar 106 is electrically connected, via solder 116, to two or more contacts of the substrate 104. For example, the substrate 104 includes a contact 148 electrically connected to the conductive structure 112 and a contact 150 electrically connected to the conductive structure 110. Although the pillar 106 is described as being electrically connected to at least one contact of the substrate 104 by the solder 116, it is noted that the solder 116 is an illustrative example of a conductive interconnect and, in other examples, another type of conductive interconnect can be used to electrically connect the pillar 106 to one or more contacts of the substrate 104.

In particular embodiments, a thickness 142 of sidewall portions the dielectric layer 114 (e.g., a cylinder wall portion of the dielectric layer 114 as illustrated in FIGS. 1B and 1C) may be limited by an allowable distance between the contacts 148, 150 of the substrate 104. For example, the allowable distance is sufficient to prevent interference or short circuits. In contrast, a thickness 140 of a top portion of the dielectric layer 114 is generally less limited. Accordingly, the thickness 142 of the sidewall portion of the dielectric layer 114 can be different from the thickness 140 of the top portion of the dielectric layer 114. To illustrate, the thickness 140 can be several orders of magnitude less than the thickness 142 such that a total capacitance of the capacitor formed by the pillar 106 is dominated by capacitance between the conductive structures 110, 112 through the top portion of the dielectric layer 114 (e.g., in a direction parallel to a normal of a top surface 105 of the substrate 104).

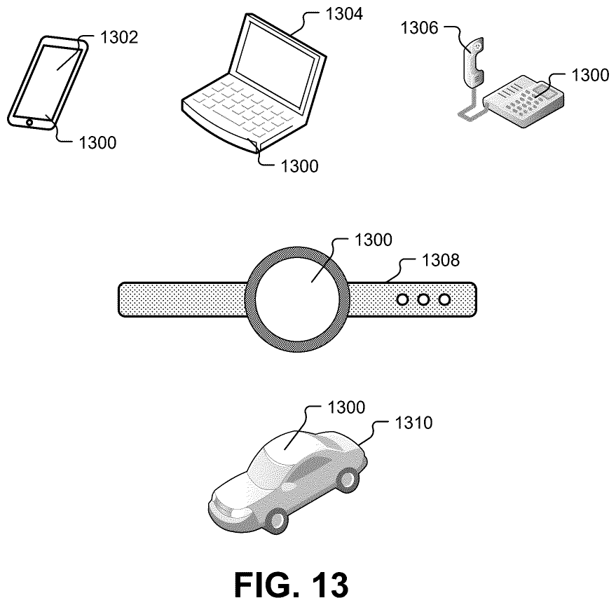

It should be understood that although the pillar 106 of FIGS. 1A-1C is shown as having a circular cross-section shape, the pillar 106 of FIGS. 1A-1C is not limited to a circular cross-section shape and can be another shape, such as oval or another shape. Further, one or more structures or layers of the pillar 106 of FIGS. 1A-1C may have a shape other than what is shown in FIGS. 1A-1C. Additionally, it should be further understood that the device 100 may include additional components, other components, fewer components, or a combination thereof, to support the functionality described herein. As non-limiting examples, the device 100 may include additional devices, additional layers, additional dies, additional packages, additional interconnects, additional structures, other components, different components, or a combination thereof, to support the functionality and technical advantages disclosed herein. In some implementations, the device 100 can be integrated in a smartphone, a tablet computer, a fixed location terminal device, an automobile, a wearable electronic device, a laptop computer, or some combination thereof, as described in more detail below with reference to FIG. 13.

The device 100 thus provides a pillar 106 that includes an embedded capacitor. A technical advantage of the pillar 106 including an embedded capacitor is that the pillar 106 may be configured to provide multiple conductive paths, such as a DC path 146 (e.g., a path that bypasses the capacitor) and an AC path 144 (e.g., a path through the capacitor). The pillar 106 configured to provide multiple conductive paths may reduce a number of electrical interconnects, such as a number of pillars, between the die 102 and the substrate 104 as compared to conventional implementations that utilize a separate pillar for each conductive path. As another technical advantage, the pillar 106 that includes the embedded capacitor may have a reduced footprint as compared to a conventional capacitor and thereby enable a reduction in die-area, increased fabrication cost savings, or a combination thereof.

In a particular implementation, the device 100 includes a die (e.g., the die 102), a substrate (e.g., the substrate 104), and a pillar (e.g., the pillar 106) having an embedded capacitor. The pillar is electrically connected to one or more conductors of the die and to one or more conductors of the substrate. The pillar includes a first conductive structure (e.g., the conductive structure 110), a second conductive structure (e.g., the conductive structure 112), and a dielectric layer (e.g., the dielectric layer 114) disposed between the first conductive structure and the second conductive structure to define the embedded capacitor.

In some implementations, a first thickness (e.g., the thickness 140) of the dielectric layer (e.g., the dielectric layer 114) separates the first conductive structure (e.g., the conductive structure 110) and the second conductive structure (e.g., the conductive structure 112) in a direction parallel to a normal of a surface (e.g., the top surface 105) of the substrate (e.g., the substrate 104). Additionally, or alternatively, a second thickness (e.g., the thickness 142) of the dielectric layer separates the first conductive structure (e.g., the conductive structure 110) and the second conductive structure (e.g., the conductive structure 112) in a direction parallel to the surface (e.g., the top surface 105) of the substrate (e.g., the substrate 104). In some implementations, the second thickness (e.g., the thickness 142) may be greater than or equal to the first thickness (e.g., the thickness 140).

In some implementations, the pillar 106 defines at least two conductive paths (e.g., the AC path 144 and the DC path 146) between the one or more conductors of substrate (e.g., the substrate 104) and the one or more conductors of the die (e.g., the die 102). The at least two conductive paths may include a direct-current path (e.g., the DC path 146) and a capacitively-coupled path (e.g., the AC path 144). In some implementations, a portion of the second conductive structure (e.g., the conductive structure 112) is common to the direct-current path (e.g., the DC path 146) and the capacitively-coupled path (e.g., the AC path 144).

In some implementations, the die 102 includes power amplifier circuitry and the substrate 104 includes conductors arranged to form an inductor of a filter. For example, the power amplifier circuitry may include or correspond to the integrated circuitry 122, and the conductors may include or correspond to one or more metal layers of the metal layers 131, 132, or 134. In some such implementations, the second conductive structure 112 is electrically connected to a collector of a transistor of the power amplifier circuitry of the die 102 and is electrically connected to a collector of a direct current circuit path (e.g., that includes or is connected to the DC path 146) of the substrate 104. Additionally, or alternatively, the second conductive structure 112 may be electrically connected to an alternating current circuit path (e.g., that includes or is connected to the AC path 144) of the filter.

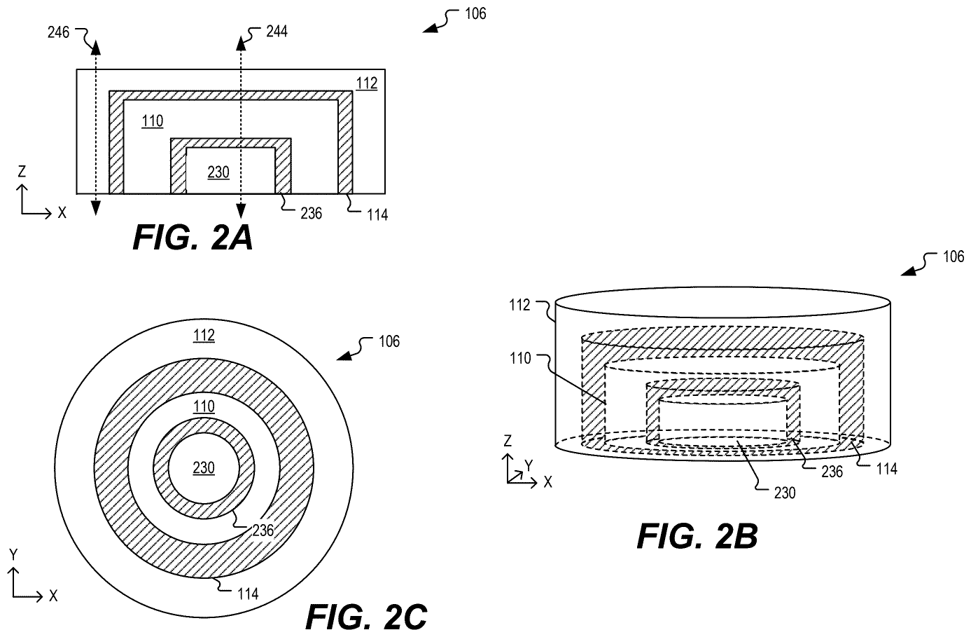

FIG. 2A illustrates a schematic cross-sectional profile view of an exemplary pillar 106 with multiple embedded capacitors. FIG. 2B illustrates a schematic perspective view of the pillar 106 with the multiple embedded capacitors, and FIG. 2C illustrates a schematic bottom view of the pillar 106 with the multiple embedded capacitors. It is noted that the pillar 106 of FIGS. 2A-C may be implemented in the device 100 of FIG. 1A as the pillar 106 or as one of the additional pillars 120.

Referring to FIGS. 2A-C, the pillar 106 of FIGS. 2A-C includes the first conductive structure 110, the second conductive structure 112, and a third conductive structure 230. The pillar 106 also includes the first dielectric layer 114 and a second dielectric layer 236.

In some implementations, the third conductive structure 230, the second dielectric layer 236, or a combination thereof, is nested within the first conductive structure 110. For example, the first conductive structure 110 may define a recess (or a cavity) and the third conductive structure 230, the second dielectric layer 236, or a combination thereof can be positioned at least partially or entirely within the recess. It is noted that the pillar 106 of FIGS. 2A-2C illustrates two embedded capacitors coupled in series as an illustrative example, and the pillar 106 may include more than two embedded capacitors coupled in series. For example, another dielectric layer and another conductive structure may be nested within a recess/cavity of the third conductive structure 230.

The third conductive structure 230, the second dielectric layer 236, and the first conductive structure 110 may define a second embedded capacitor. To illustrate, a first embedded capacitor may include the first conductive structure 110, the second conductive structure 112, and the first dielectric layer 114, and the second embedded conductor may include the first conductive structure 110, the third conductive structure 130, and the second dielectric layer 136. In some implementations, the first embedded capacitor and the second embedded capacitor are coupled electrically in series with one another between the one or more conductors of the die 102 and the one or more conductors of the substrate 104. For example, an AC path passes through the first embedded capacitor followed by the second embedded capacitor. It should be understood that although the pillar 106 of FIGS. 2A-2C is shown as having a circular cross-section shape, the pillar 106 of FIGS. 2A-2C is not limited to a circular cross-section shape and can be another shape, such as oval or another shape. Further, one or more structures or layers of the pillar 106 of FIGS. 2A-2C may have a shape other than what is shown in FIGS. 2A-2C.

The pillar 106 of FIGS. 2A-C thus includes multiple embedded capacitors. A technical advantage of the pillar 106 is that the pillar 106 may be configured to provide multiple conductive paths, such as a DC path 246 (e.g., a path that bypasses the capacitors) and an AC path 244 (e.g., a path through the first embedded capacitor, or a path through both the first and second embedded capacitors). The pillar 106 configured to provide the multiple conductive paths may reduce a number of electrical interconnects between the die 102 and the substrate 104 as compared to conventional implementations that utilize a separate pillar for each conductive path. As another technical advantage, the pillar 106 that includes the embedded capacity may have a reduced footprint as compared to a conventional capacitor and thereby enable a reduction in die-area, increased fabrication cost savings, or a combination thereof.

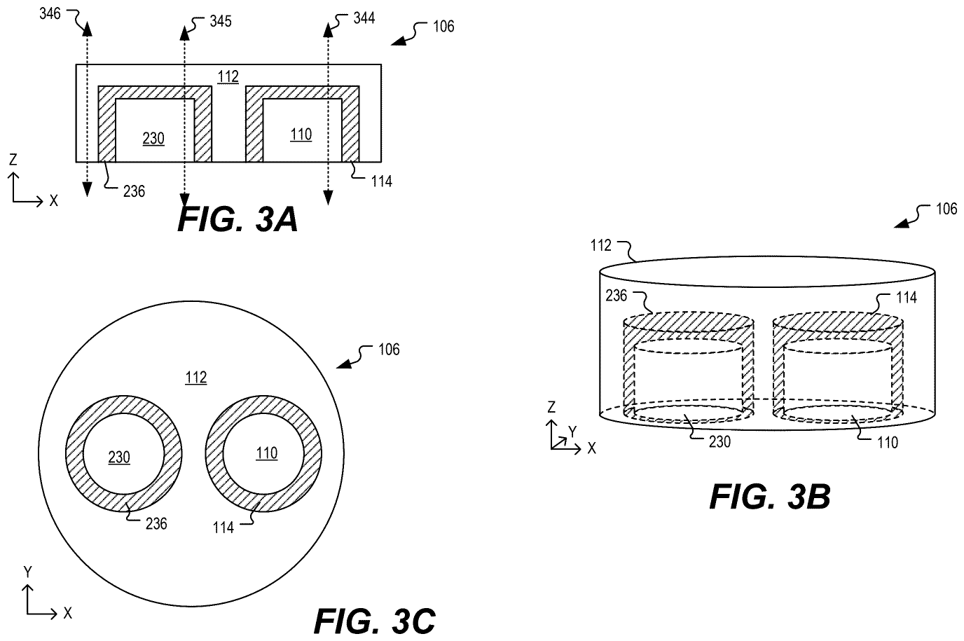

FIG. 3A illustrates a schematic cross-sectional profile view of an exemplary pillar 106 with multiple embedded capacitors. FIG. 3B illustrates a schematic perspective view of the pillar 106 with the multiple embedded capacitors, and FIG. 3C illustrates a schematic bottom view of the pillar 106 with the multiple embedded capacitors. It is noted that the pillar 106 of FIGS. 3A-C may be implemented in the device 100 of FIG. 1A as the pillar 106 or as one of the additional pillars 120.

Referring to FIGS. 3A-C, the pillar 106 of FIGS. 3A-C includes the first conductive structure 110, the second conductive structure 112, and the third conductive structure 230. The pillar 106 also includes the first dielectric layer 114 and the second dielectric layer 236.

The third conductive structure 230, the second dielectric layer 236, and the second conductive structure 112 may define a second embedded capacitor. To illustrate, a first embedded capacitor may include the first conductive structure 110, the second conductive structure 112, and the first dielectric layer 114, and the second embedded conductor may include the second conductive structure 112, the third conductive structure 230, and the second dielectric layer 236.

In some implementations, the first conductive structure 110, the first dielectric layer 114, or a combination thereof, is positioned within a first recess (or cavity) of the second conductive structure 112. For example, the second conductive structure 112 may define the first recess (or a cavity) and the first conductive structure 110, the first dielectric layer 114, or a combination thereof can be positioned at least partially or entirely within the first recess. Additionally, or alternatively, the third conductive structure 230, the second dielectric layer 236, or a combination thereof, is positioned within a second recess (or cavity) of the second conductive structure 112. For example, the second conductive structure 112 may define the second recess (or a cavity) and the third conductive structure 230, the second dielectric layer 236, or a combination thereof can be positioned at least partially or entirely within the second recess. In some implementations, the third conductive structure 230 is disposed side-by-side with the first conductive structure 110. It is noted that the pillar 106 of FIGS. 3A-C illustrates two embedded capacitors coupled in series as an illustrative example, and the pillar 106 may include more than two embedded capacitors positioned side-by-side. For example, another dielectric layer and another conductive structure may be nested within another recess/cavity of the second conductive structure 112. Additionally, or alternatively, in some other implementations, at least one of the first conductive structure 110 or the third conductive structure 230 includes a recess/cavity in which one or more dielectric layers and one or more additional conductive structures are positioned. It should be understood that although the pillar 106 of FIGS. 3A-3C is shown as having a circular cross-section shape, the pillar 106 of FIGS. 3A-3C is not limited to a circular cross-section shape and can be another shape, such as oval or another shape. Further, one or more structures or layers of the pillar 106 of FIGS. 3A-3C may have a shape other than what is shown in FIGS. 3A-3C.

In some implementations, the first embedded capacitor and the second embedded capacitor are coupled electrically in parallel with one another between one or more conductors of the die 102 and one or more conductors of the substrate 104. As an illustrative, non-limiting example, the first embedded capacitor and the second embedded capacitor may be coupled to the same conductor of the die 102 and may be connected to different conductors of the substrate 104. In some implementations, the first embedded capacitor is coupled to ground (e.g., directly or via a first set of one or more components) and the second embedded capacitor is coupled to ground (e.g., directly or via a second set of one or more components). In some examples, the first embedded capacitor may be coupled to a first connection point of the die 102 and a first connection point of the substrate 104, and the second embedded capacitor may be coupled to a second connection point of the die 102 and a second connection point of the substrate 104.

The pillar 106 of FIGS. 3A-C thus includes multiple embedded capacitors. A technical advantage of the pillar 106 is that the pillar 106 may be configured to provide multiple conductive paths, such as a DC path 346 (e.g., a path that bypasses the capacitor) and an AC path (e.g., a first AC 344 path through the first embedded capacitor or a second path 345 through the second embedded capacitor). The pillar 106 configured to provide the multiple conductive paths may reduce a number of electrical interconnects between the die 102 and the substrate 104 as compared to conventional implementations that utilize a separate pillar for each conductive path. As another technical advantage, the pillar 106 that includes the embedded capacity may have a reduced footprint as compared to a conventional capacitor and thereby enable a reduction in die-area, increased fabrication cost savings, or a combination thereof.

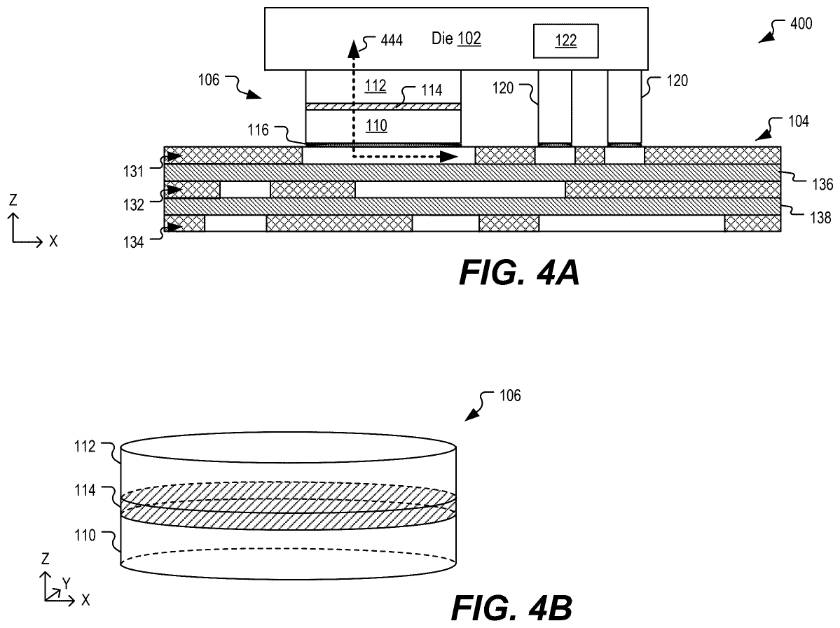

FIG. 4A illustrates a schematic cross-sectional profile view of an exemplary device 400 that includes a pillar 106 with an embedded capacitor. The device 400 also includes a die 102 and a substrate 104. The pillar 106 with the embedded capacitor is electrically coupled to one or more conductors of the die 102 and to one or more conductors of the substrate 104. FIG. 4B illustrates a schematic perspective view of the pillar 106. It is noted that the pillar 106 of FIGS. 4A-B may be implemented in the device 100 of FIG. 1A as one of the pillars 120.

Referring to FIGS. 4A-B, the pillar 106 includes the first conductive structure 110, the second conductive structure 112, and the dielectric layer 114. The dielectric layer 114 is positioned between (e.g., interposed between) the first conductive structure 110 and the second conductive structure 112. Accordingly, the pillar 106 may be configured to provide an AC path 444. In some aspects, a DC path is not provided by the pillar 106. In addition to the pillar 106, the device 400 can include one or more additional pillars 120 electrically connected to one or more conductors of the die 102 and to one or more conductors of the substrate 104. One or more of the additional pillars 120 can include a conventional copper pillar. Alternatively, or additionally, one or more of the additional pillars 120 can include an embedded capacitor, similar to the pillar 106 of FIG. 1A, the pillar 106 of FIG. 4A, or both.

In some implementations, one or more aspects of the pillar 106 of FIG. 1A-C, 2A-C, or 3A-C may be combined with or incorporated into the pillar 106 of FIGS. 4A-B. For example, one or more dielectric layers and one or more conductive structures may be formed in a recess defined by the first conductive structure 110 of FIGS. 4A-B. Accordingly, the pillar 106 of FIGS. 4A-B may include multiple embedded capacitors, such multiple nested capacitors, multiple side-by-side capacitors, or a combination thereof. It should be understood that although the pillar 106 of FIGS. 4A-4B is shown as having a circular cross-section shape, the pillar 106 of FIGS. 4A-4B is not limited to a circular cross-section shape and can be another shape, such as oval or another shape. Further, one or more structures or layers of the pillar 106 of FIGS. 4A-4B may have a shape other than what is shown in FIGS. 4A-4B.

The pillar 106 of FIGS. 4A-B thus includes an embedded capacitor configured to provide an AC path. As a technical advantage, the pillar 106 that includes the embedded capacitor may have a reduced footprint as compared to a conventional capacitor and thereby enable a reduction in die-area, increased fabrication cost savings, or a combination thereof.

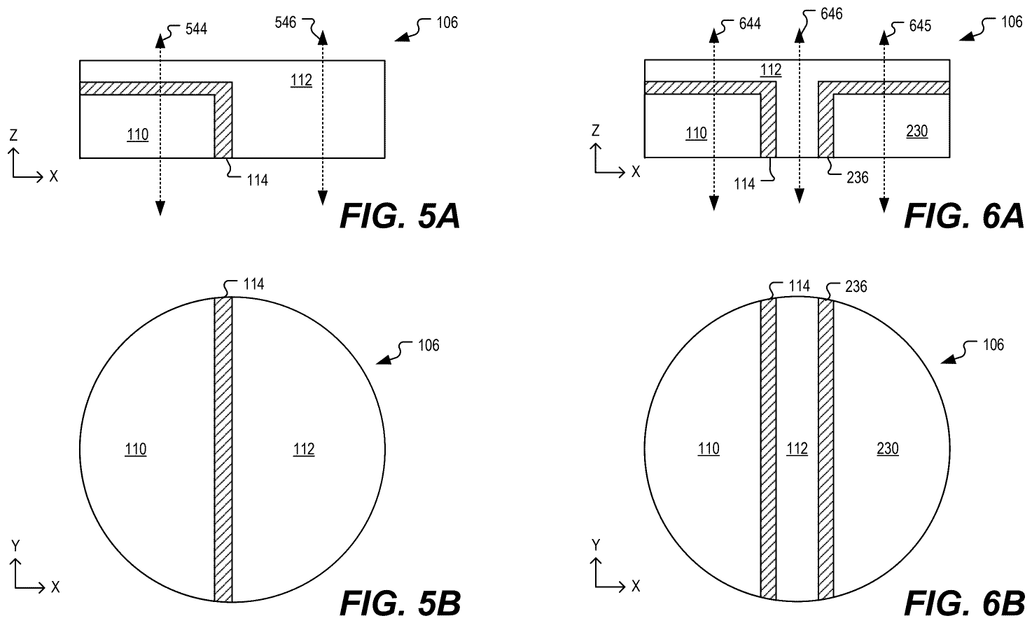

FIG. 5A illustrates a schematic cross-sectional profile view of an exemplary pillar with an embedded capacitor. FIG. 5B illustrates a schematic bottom view of the pillar with the embedded capacitors of FIG. 5A. It is noted that the pillar 106 of FIGS. 5A-B may be implemented in the device 100 of FIG. 1A as the pillar 106 or as one of the additional pillars 120, in the device 400 of FIG. 4A as the pillar 106 or as one of the additional pillars 120, or a combination thereof.

Referring to FIGS. 5A-B, the pillar 106 of FIGS. 5A-B includes the first conductive structure 110, the second conductive structure 112, and the dielectric layer 114. The dielectric layer 114 is positioned between (e.g., interposed between) the first conductive structure 110 and the second conductive structure 112. Each of the pillars 106 of FIGS. 1A, 4A, and 5A provide illustrative examples of physical structures that include a single embedded capacitor. It should be understood that although the pillar 106 of FIGS. 5A-5B is shown as having a circular cross-section shape, the pillar 106 of FIGS. 5A-5B is not limited to a circular cross-section shape and can be another shape, such as oval or another shape. Further, one or more structures or layers of the pillar 106 of FIGS. 5A-5B may have a shape other than what is shown in FIGS. 5A-5B. Additionally, it should be further understood that other physical structures of the pillar 106 with an embedded capacitor are possible. The particular physical configurations of the pillar 106 can enable different connection options of the pillar 106 with the substrate 104. For example, the pillar 106 of FIG. 1A can include one or more AC paths between sets of DC paths, the pillar 106 of FIG. 4A can include one or more AC paths without any DC paths, and the pillar 106 of FIG. 5A can include one or more AC paths in one portion of the pillar 106 and one or more DC paths in another portion of the pillar 106. The alternative connection options may provide design flexibility when designing a device, such as the device 100 or the device 400.

The pillar 106 of FIGS. 5A-5B has a technical advantage in that the pillar 106 may be configured to provide multiple conductive paths, such as a DC path 546 (e.g., a path that bypasses the capacitor) and an AC path 544 (e.g., a path through the capacitor). The pillar 106 configured to provide multiple conductive paths may reduce a number of electrical interconnects between the die 102 and the substrate 104 as compared to conventional implementations that utilize a separate pillar for each conductive path. As another technical advantage, the pillar 106 that includes the embedded capacitor may have a reduced footprint as compared to a conventional capacitor and thereby enable a reduction in die-area, increased fabrication cost savings, or a combination thereof. In some implementations, one or more aspects of the pillar 106 of FIG. 1A-C, 2A-C, or 3A-C may be combined with or incorporated into the pillar 106 of FIGS. 5A-B. For example, one or more dielectric layers and one or more conductive structures may be formed in a recess defined by the first conductive structure 110 of FIGS. 5A-B or in a recess defined by the second conductive structure 112 of FIGS. 5A-B. Additionally, or alternatively, a recess defined by the first conductive structure 110 of FIGS. 5A-B may include another dielectric layer having the same shape as the dielectric layer 114 of FIGS. 5A-B and another conductive structure, such that the other dielectric layer is positioned between the first conductive structure and the other conductive structure to form another embedded capacitor. Accordingly, the pillar 106 of FIGS. 5A-B may include multiple embedded capacitors, such multiple nested capacitors, multiple side-by-side capacitors, or a combination thereof.

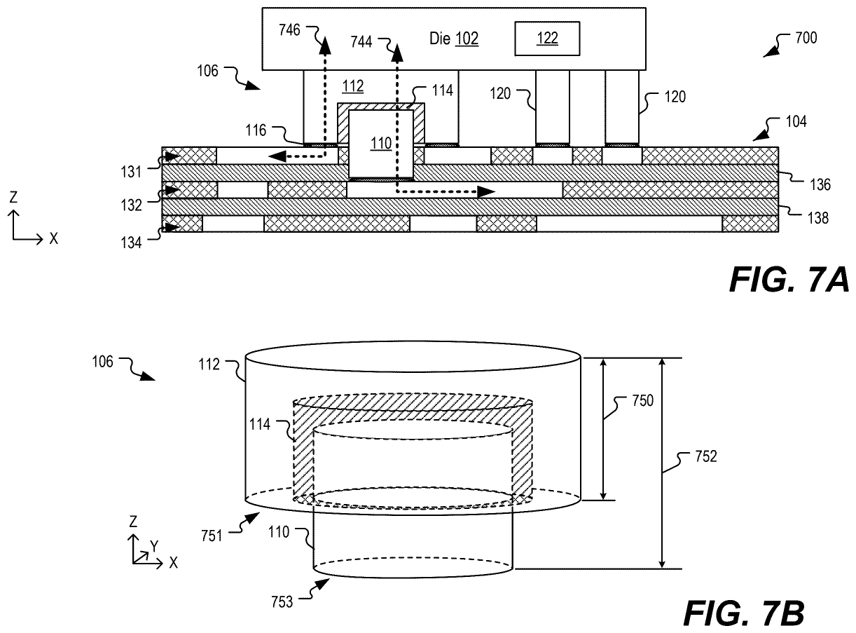

FIG. 6A illustrates a schematic cross-sectional profile view of an exemplary pillar with multiple embedded capacitors. FIG. 6B illustrates a schematic bottom view of the pillar with multiple embedded capacitors of FIG. 6A. It is noted that the pillar 106 of FIGS. 6A-B may be implemented in the device 100 of FIG. 1A as the pillar 106 or as one of the additional pillars 120, in the device 400 of FIG. 4A as the pillar 106 or as one of the additional pillars 120, or a combination thereof.

Referring to FIGS. 6A-B, the pillar 106 of FIGS. 6A-B includes the first conductive structure 110, the second conductive structure 112, and the third conductive structure 230. The pillar 106 also includes the first dielectric layer 114 and the second dielectric layer 236.

The second conductive structure 112, the third conductive structure 230, and the second dielectric layer 236 may define a second embedded capacitor. To illustrate, a first embedded capacitor may include the first conductive structure 110, the second conductive structure 112, and the first dielectric layer 114, and the second embedded conductor may include the second conductive structure 112, the third conductive structure 230, and the second dielectric layer 236.

In some implementations, one or more aspects of the pillar 106 of FIG. 1A-C, 2A-C, 3A-C, 4A-B, or 5A-B may be combined with or incorporated into the pillar 106 of FIGS. 6A-B. For example, one or more dielectric layers and one or more conductive structures may be formed in a recess defined by the first conductive structure 110 of FIGS. 6A-B, in a recess defined by the second conductive structure 112 of FIGS. 6A-B, or in a recess defined by the third conductive structure 230 of FIGS. 6A-B.

Accordingly, the pillar 106 of FIGS. 6A-B may include multiple embedded capacitors, such multiple nested capacitors, multiple side-by-side capacitors, or a combination thereof. It should be understood that although the pillar 106 of FIGS. 6A-6B is shown as having a circular cross-section shape, the pillar 106 of FIGS. 6A-6B is not limited to a circular cross-section shape and can be another shape, such as oval or another shape. Further, one or more structures or layers of the pillar 106 of FIGS. 6A-6B may have a shape other than what is shown in FIGS. 6A-6B.

Each of the pillars 106 of FIGS. 2A, 3A, and 6A provide examples of physical structures that include multiple embedded capacitors. It should be understood that other physical structures of the pillar 106 with multiple embedded capacitors are possible. The particular physical configurations of the pillar 106 enable different connection options of the pillar 106 with the substrate 104. For example, the different connection options may include different connection shapes, different connection placement, different current capacities, or a combination thereof. The alternative connection options may provide design flexibility when designing a device, such as the device 100 or the device 400.

The pillar 106 of FIG. 6A-B thus includes multiple embedded capacitors. A technical advantage of the pillar 106 is that the pillar 106 may be configured to provide multiple conductive paths, such as a DC path 646 (e.g., a path that bypasses the capacitor) and an AC path (e.g., a first path 644 through the first embedded capacitor and a second path 645 through the second embedded capacitor). The pillar 106 configured to provide multiple conductive paths may reduce a number of electrical interconnects between the die 102 and the substrate 104 as compared to conventional implementations that utilize a separate pillar for each conductive path. As another technical advantage, the pillar 106 that includes the embedded capacitors may have a reduced footprint as compared to conventional capacitors and thereby enable a reduction in die-area, increased fabrication cost savings, or a combination thereof.

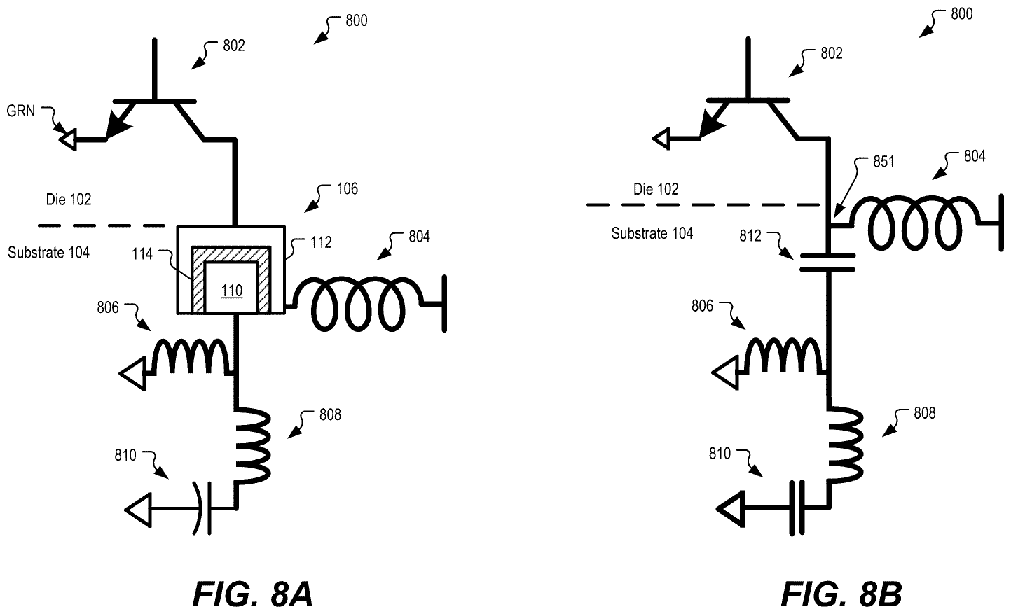

FIG. 7A illustrates a schematic cross-sectional profile view of an exemplary device 700 that includes a pillar 106 with an embedded capacitor. The device 700 also includes a die 102 and a substrate 104. The pillar 106 with the embedded capacitor is electrically coupled to one or more conductors of the die 102 and to one or more conductors of the substrate 104. FIG. 7B illustrates a schematic perspective view of the pillar 106 of FIG. 7A. It is noted that the pillar 106 of FIGS. 7A-B may be implemented in the device 100 of FIG. 1A as one of the pillars 120, in the device 400 of FIG. 4A as one of the pillars 120, or a combination thereof.

Referring to FIGS. 7A-B, the pillar 106 includes the first conductive structure 110, the second conductive structure 112, and the dielectric layer 114. The dielectric layer 114 is positioned between the first conductive structure 110 and the second conductive structure 112. An end 753 of the first conductive structure 110 is a first distance from the die 102 and an end 751 of the second conductive structure 112 is a second distance 750 from the die 102. The first distance 752 may be greater than or equal to the second distance 750.

As compared to the device 100 of FIGS. 1A-C, the device 700 of FIGS. 7A-B is able to reduce a size of or remove one or more structures of the substrate 104. For example, the device 700 of FIGS. 7A-B is able to reduce a size of or remove the contact 150, a via structure, or a combination thereof, as compared to the device 100 of FIGS. 1A-C. Accordingly, the physical configuration of the pillar 106 of FIGS. 7A-B enables different connection options of the pillar 106 of FIGS. 7A-B with the substrate 104 as compared to the pillar 106 of FIGS. 1A-C. For example, the different connection options may include different connection shapes, different connection placement, different current capacities, or a combination thereof. The alternative connection options between FIGS. 1A-C and 7A-B may provide design flexibility when designing a device, such as the device 100, the device 400, the device 700, or a combination thereof. It should be understood that although the pillar 106 of FIGS. 7A-7B is shown as having a circular cross-section shape, the pillar 106 of FIGS. 7A-7B is not limited to a circular cross-section shape and can be another shape, such as oval or another shape. Further, one or more structures or layers of the pillar 106 of FIGS. 7A-7B may have a shape other than what is shown in FIGS. 7A-7B.

It is also noted that a relationship between the end 753 of the first conductive structure 110 and the end 751 of the second conductive structure 112 as described with reference to the pillar 106 of FIGS. 7A-7B, may also be applied to the pillar 106 of FIGS. 2A-6B. For example, referring to FIG. 2A, an end of the first conductive structure 110 may be a first distance from the die 102, an end of the second conductive structure 112 may be a second distance from the die 102, and an end of the third conductive structure 230 may be a third distance from the die 102. The third distance may be greater than or equal to the first distance or the second distance. Additionally, or alternatively, the first distance may be greater than, equal to, or less than the third distance. As another example, referring to FIG. 3A, an end of the first conductive structure 110 may be a first distance from the die 102, an end of the second conductive structure 112 may be a second distance from the die 102, and an end of the third conductive structure 230 may be a third distance form the die 102. The first distance may be greater than or equal to the second distance and/or the third distance. Additionally, or alternatively, the third distance may be greater than or equal to the second distance. As another example, referring to FIG. 5A, an end of the first conductive structure 110 may be a first distance from the die 102, and an end of the second conductive structure 112 may be a second distance from the die 102. The first distance may be greater than or equal to the second distance.

The pillar 106 of FIGS. 7A-B thus includes an embedded capacitor. A technical advantage of the pillar 106 is that the pillar 106 may be configured to provide multiple conductive paths, such as a DC path 746 and an AC path 744. The pillar 106 configured to provide multiple conductive paths may reduce a number of electrical interconnects between the die 102 and the substrate 104 as compared to conventional implementations that utilize a separate pillar for each conductive path. As another technical advantage, the pillar 106 that includes the embedded capacity may have a reduced footprint as compared to a conventional capacitor and thereby enable a reduction in die-area, increased fabrication cost savings, or a combination thereof.

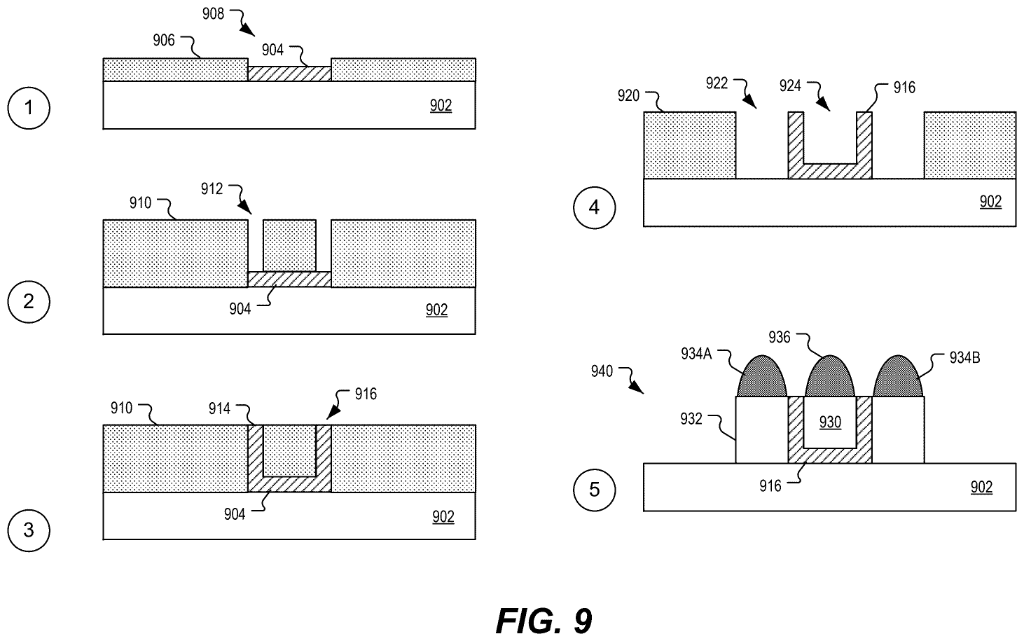

FIG. 8A illustrates a diagram illustrating aspects of a circuit of a device 800 that includes an exemplary pillar with an embedded capacitor, and FIG. 8B illustrates a schematic circuit diagram of the device 800. Each of diagrams depicts the device 800 with reference to the die 102 and the substrate 104.

Referring to FIG. 8A, the device 800 includes a transistor 802, the pillar 106, inductors 804, 806, and 808, and a capacitor 810. In some implementations, the die 102 includes the transistor 802. For example, the transistor 802 may include or correspond to the integrated circuitry 122 of FIG. 1. A collector of the transistor 802 may be coupled to the pillar 106, such as to the second conductive structure 112 of the pillar 106. The pillar 106 includes the first conductive structure 110, the second conductive structure 112, and the dielectric layer 114. Although depicted as the pillar 106 of FIGS. 1A-C, the pillar 106 may include the pillar 106 of any of FIG. 2A-C, 3A-C, 4A-B, 5A-B, 6A-B, or 7A-B.

The substrate 104 may include the pillar 106, the inductors 804, 806, and 808, the capacitor 810, or a combination thereof. For example, at least one of the inductors 804, 806, or 808 may include or correspond to the metal layers 131-134 of FIG. 1. For example, the metal layer 131 may be configured as the inductor 804, such as a choke inductor. Additionally, or alternatively, the metal layer 132 may be configured as one or more inductors, such as a first inductor (e.g., the inductor 806) and a second inductor (e.g., the inductor 808). Additionally, or alternatively, inductors 804, 806, and 808, the capacitor 810, or a combination thereof, may be arranged or configured as a filter. The capacitor 810 may include or correspond to a polarized fixed capacitor. In some implementations, the pillar 106 is positioned between the die 102 and the substrate 104 and is configured to be electrically coupled to the die 102 and to the substrate 104.

In some implementations, the device 800 includes the die 102 and the substrate 104. The die 102 includes power amplifier circuitry and the substrate 104 includes conductors arranged to form an inductor of a filter. The second conductive structure 112 may be electrically connected to a collector of the transistor 802 of the power amplifier circuitry of the die 102. Additionally, or alternatively, the second conductive structure 112 can be electrically connected to a collector of a direct current circuit path, such as the DC signal path 146, of the substrate 104. For example, the direct current circuit path may include the inductor 804 In some such implementations, the first conductive structure 110 is electrically connected to an alternating current circuit path (e.g., the capacitively coupled signal path 144) of the filter, such as a filter that includes the inductors 806 and 808, and the capacitor 810.

Referring to FIG. 8B, the pillar 160 corresponds to a capacitor 812 (e.g., the embedded capacitor) and a node 851 (e.g., a connection point).

Exemplary Sequence for Fabricating a Device/IC Device Including a Pillar with an Embedded Capacitor

In some implementations, fabricating a device including a pillar (e.g., the pillar 106 or additional pillar 120) with an embedded capacitor includes several processes. FIG. 9 illustrates an exemplary sequence for fabricating or providing a device that includes a pillar with an embedded capacitor, as described with reference to any of FIGS. 1A-C and 3A-C. In some implementations, the sequence of FIG. 9 may be used to provide (e.g., during fabrication of) one or more of the device 100 of FIGS. 1A-C, the device 400 of FIGS. 4A-4B, the device 700 of FIGS. 7A-7B, the device 800 of FIGS. 8A-8B, or a combination thereof.

It should be noted that the sequence of FIG. 9 may combine one or more stages in order to simplify and/or clarify the sequence for providing or fabricating a device that includes a pillar (e.g., the pillar 106 or additional pillar 120). In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 9. Each of the various stages of the sequence illustrated in FIG. 9 shows a pillar (e.g., the pillar 106 or additional pillar 120) with an embedded capacitor being formed. In other implementations, a single pillar may be formed or multiple pillars can be formed concurrently. It is noted that the various stages of FIG. 9 depict a cross-sectional profile view of formation of a device.

Stage 1 of FIG. 9 illustrates a state after a dielectric layer 904 is formed on a metal layer 902. For example, as part of Stage 1, the dielectric layer 904 may be formed in a recess 908 formed in a photo resist layer 906. To illustrate, the photo resist layer 906 may be formed on the metal layer 902 and patterned. An etch process may be performed based on a pattern to form the recess 908 and expose a portion of a surface of the metal layer 902. After formation of the dielectric layer 904, a planarization operation or photo resist etch/removal operation may be performed. In some implementations, the metal layer 902 may be electrically connected to the one or more conductors of a die, such as the die 102.

Stage 2 illustrates a state after formation of a photo resist 910. For example, as part of Stage 2, the photo resist 910 may be formed on the dielectric layer 904, the photo resist layer 906, or a combination thereof. As part of Stage 2, the photo resist 910 includes a recess 912.

Stage 3 illustrates a state after formation of a dielectric layer 916. For example, as part of Stage 3, a dielectric material may be formed in the recess 912. Accordingly, the dielectric layer 916 includes the dielectric layer 904, one or more dielectric walls 914, or a combination thereof. As shown, the dielectric layer 916 is formed on the metal layer 902. After formation of the dielectric layer 916, a planarization operation may be performed.

Stage 4 illustrates a state after formation of one or more recesses 922 or 924. For example, as part of Stage 4, a photo resist layer 920 may be patterned, and an etch process may be performed based on a pattern to form the one or more recesses 922 or 924. A first recess 922 may expose a portion of the metal layer 902, and a second recess 924 may expose a surface of the dielectric layer 916 (e.g., a surface of dielectric layer 904). In some implementations, the one or more dielectric walls 914 may define the second recess 924 (e.g., a cavity).

In some implementations, as part of Stage 4, the photo resist 910 may be removed and a plating/seed operation may be performed on the dielectric layer 916, the metal layer 902, or a combination thereof. After the plating/seed operation, the photo resist layer 920 may be formed, patterned, and etched to form the one or more recesses 922 or 924.

Stage 5 illustrates a state after formation of a device 940 (e.g., a pillar). For example, as part of Stage 5, one or more conductive structures may be formed, such as a first conductive structure 930 or a second conductive structure 932. To illustrate, as part of Stage 5, metal, such as copper, may be deposited to form the first conductive structure 930 on the dielectric layer 916. Additionally, or alternatively, metal (e.g., copper) may be deposited surrounding the one or more dielectric walls (e.g., the one or more dielectric walls 914) of the dielectric layer 916 to form the second conductive structure 932.

As part of Stage 5, one or more conductive interconnects (e.g., solder caps) may be formed, such as a solder cap 934A, a solder cap 934B, a solder cap 936, or a combination thereof. To illustrate, the solder cap 935 may be formed on the first conductive structure 930. Additionally, or alternatively, the solder cap 934 may be formed on the second conductive structure 932.

The device 940 includes a pillar configured to be electrically connected to one or more conductors of a die. For example, the pillar may include or correspond to the pillar 106 of FIGS. 1A-C. The pillar includes the first conductive structure 930, the second conductive structure 932, and the dielectric layer 916 disposed between the first conductive structure 930 and the second conductive structure 932 to define an embedded capacitor. For example, the first conductive structure 930, the second conductive structure 932, and the dielectric layer 916 may include or correspond to the first conductive structure 110, the second conductive structure 112, and the dielectric layer 114, respectively.

Formation of the device 940 (e.g., a device including a pillar with an embedded capacitor) is complete after Stage 5 of FIG. 9. The device 940 (e.g., the pillar) may include or correspond to the pillar 106 as described herein at least with reference to FIGS. 1A-C.

Although certain Stages are illustrated in FIG. 9 in forming the device 940 (e.g., the pillar), other processes can be included in the fabrication of a device that includes a pillar as described with reference to FIG. 3A-C, 4A-B, 5A-B, 6A-B, or 7A-B without departing from the scope of the subject disclosure. For example, fabricating the pillar 106 of FIGS. 3A-C can include performing Stages 1-4 of FIG. 9 such that two dielectric layers (e.g., dielectric layers 916) are formed. For example, the two dielectric layers, such as a first dielectric layer and a second dielectric layer, may be formed side-by-side on the metal layer 902 in two recesses 908 in the photo resist layer 906. For each dielectric layer, one or more walls of the dielectric layer may define a recess 924. Accordingly, a first recess and a second recess may be defined. Stage 5 of FIG. 9 may be modified to deposit metal in each of the first and second recesses, such that the first conductive structure 930 is formed in the first recess of the first dielectric layer, and a third conductive structure is formed in the second recess of the second dielectric layer. For example, the second dielectric layer and the third conductive structure may include or correspond to the dielectric layer 136 and the third conductive structure 230 of FIG. 3A, respectively. A conductive interconnect (e.g., a solder cap) may be formed on the third conductive structure.

As another example, fabricating the pillar 106 of FIGS. 4A-B can include depositing a metal (of the second conductive structure) in recess 908 prior to performing Stage 1 of FIG. 9. At Stage 2 of FIG. 9, the etch may be performed to form the recess 912 such that the photo resist material is not above the dielectric layer 904. A metal may then be deposited in the recess 912 to form the first conductive structure. The photo resist 910 may then be removed. Additionally, or alternatively, a conductive interconnect (e.g., a solder cap) may be formed on the first conductive structure.

As another example, fabricating the pillar 106 of FIGS. 5A-B can include depositing a metal (of the second conductive structure) in recess 908 prior to performing Stage 1 of FIG. 9. At Stage 2 of FIG. 9, the etch may be performed to form the recess 912 that exposes a portion of the dielectric layer 904. At Stage 3 of FIG. 9, a dielectric material may be deposited to form the dielectric layer 916 that includes a single wall. Stages 4 and 5 of FIG. 9 may be performed to form the first and second conductive structure having conductive interconnects formed thereon. To fabricate the pillar 106 of FIGS. 6A-B, a similar method may be performed as described with reference to fabricating the pillar 106 of FIGS. 5A-B. However, at Stage 1 of FIG. 9, two separate dielectric layers may be formed, and at Stage 2 of FIG. 9, two recesses may be formed, such as one recess that exposes a portion of the first dielectric layer and a second recess that exposes a portion of the second dielectric layer. At Stage 3 of FIG. 9, a dielectric material may be deposited to form the two dielectric layers (e.g., the first dielectric layer 114 and the second dielectric layer 236) that each have a single wall. Stages 4 and 5 of FIG. 9 may be performed to form the first, second, and third conductive structure having conductive interconnects formed thereon.

As another example, fabricating the pillar 106 of FIGS. 7A-B can include performing Stages 1-4 of FIG. 9. As part of Stage 5 of FIG. 9, a photo resist material may be deposited, patterned, and etched to form a recess in the photo resist layer the corresponds to an additional portion of the first conductive structure. A metal material may be deposited in the recess to form the first conductive structure 930. The photo resist material may then be removed. Additionally, or alternatively, conductive interconnects (e.g., solder caps) may be formed on the first conductive structure 930 and the second conductive structure 932.

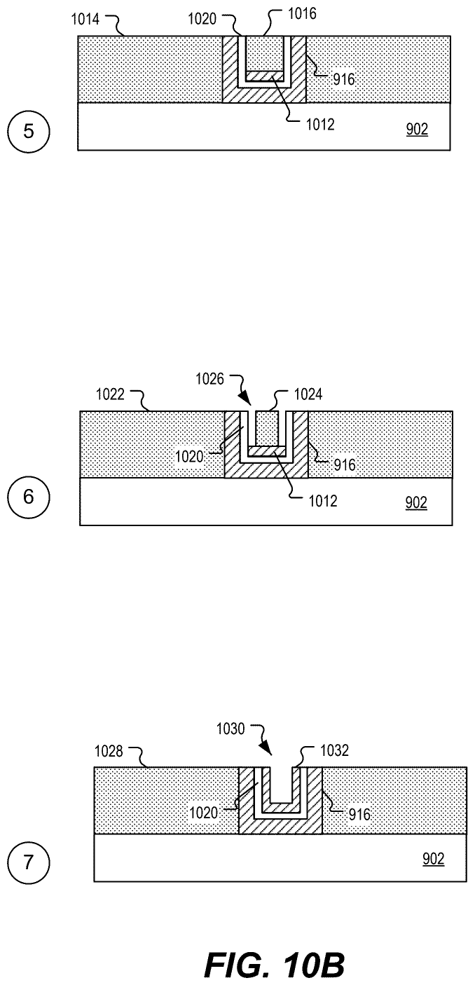

In some implementations, fabricating a device including a pillar (e.g., a pillar 106 or a pillar 120) with an embedded capacitor includes several processes. FIGS. 10A-C illustrate an exemplary sequence for fabricating or providing a device that includes a pillar with an embedded capacitor, as described with reference to FIGS. 2A-C. In some implementations, the sequence of FIGS. 10A-C may be used to provide (e.g., during fabrication of) one or more of the device 100 of FIGS. 1A-C, the device 400 of FIGS. 4A-B, the device 700 of FIGS. 7A-B, the device 800 of FIGS. 8A-B, or a combination thereof.

It should be noted that the sequence of FIGS. 10A-C may combine one or more stages in order to simplify and/or clarify the sequence for providing or fabricating a device that includes a pillar (e.g., a pillar 106 or a pillar 120). In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 10A-C. Each of the various stages of the sequence illustrated in FIGS. 10A-C shows a pillar (e.g., a pillar 106 or a pillar 120) with an embedded capacitor being formed. In other implementations, a single pillar may be formed or multiple pillars can be formed concurrently. It is noted that the various stages of FIGS. 10A-C depict a cross-sectional profile view of formation of a device.

Stage 1 of FIG. 10A illustrates a state after the dielectric layer 916 is formed on a metal layer 902. For example, as part of Stage 1, one or more operations may be performed as described with reference to Stages 1-3 of FIG. 9 to form the dielectric layer 916. After formation of the dielectric layer 916 at Stage 3 of FIG. 9, a portion of the photo resist 910 may be removed to obtain Stage 1 of FIG. 10A where the dielectric layer 916 includes one or more dielectric walls 914 defining a first recess 1004. In some implementations, the metal layer 902 may be electrically connected to the one or more conductors of a die, such as the die 102.

Stage 2 illustrates a state after a first portion 1006 of a first conductive structure is formed. For example, as part of Stage 2, a metal, such as copper, may be deposited within the first recess 1004 to form the first portion 1006 of the first conductive structure. To illustrate, the first portion 1006 of the first conductive structure may be formed on the dielectric layer 916.

Stage 3 illustrates a state after a first portion 1012 of a second dielectric layer is formed on the first portion 1006 of the first conductive structure. For example, as part of Stage 3, the photo resist layer 1002 is removed and a photo resist material (of a photo resist layer 1008, 1010) is deposited and patterned. An etch process may be performed based on a pattern to form a recess (defined by the photo resist layer 1010) and expose part of a surface of the first portion 1006 of the first conductive structure. The first portion 1012 of the second dielectric layer is formed in the recess (defined by the photo resist layer 1010).

Stage 4 illustrates a state after a recess 1018 is formed. For example, as part of Stage 4, the photo resist layer 1008 and 1010 may be removed and a photo resist material (of the photo resist layer 1014, 1016) is deposited and patterned. An etch process may be performed based on a pattern to form the recess 1018 (defined by the photo resist layer 1016 and the dielectric walls 914 of the dielectric layer 916) and expose part of a surface of the first portion 1006 of the first conductive structure.

Stage 5 of FIG. 10B illustrates a state after a second portion of a first conductive structure 1020 is formed. For example, as part of Stage 5, metal may be deposited within the recess 1018 on the first portion 1006 of the first conductive structure 1020 to form a second portion of the first conductive structure 1020. To illustrate, metal, such as copper, may be deposited to form the second portion of the first conductive structure 1020 including one or more walls. The one or more walls of the first conductive structure 1020 may define a recess (or cavity) in which the first portion 1012 of the second dielectric layer and the photo resist layer 1016 are positioned.

Stage 6 illustrates a state after a recess 1026 is formed. For example, as part of Stage 6, the photo resist layers 1014 and 1016 may be patterned, and an etch process may be performed based on a pattern to form the recess 1026 and photo resist layers 1022 and 1024.

Stage 7 illustrates a state after a second dielectric layer 1032 is formed. For example, as part of Stage 7, a dielectric material may be deposited in the recess 1026. To illustrate, the dielectric material may be deposited to form a second portion of the second dielectric layer 1032 within the recess 1026 and on the first portion 1012 of the second dielectric layer 1032. The second portion of the second dielectric layer 1032 may include one or more dielectric walls defining a recess 1030. In some implementations, a planarization operation may be performed after the dielectric material is deposited. After the dielectric material is deposited, the photo resist layers 1022 and 1024 may be patterned, and an etch process may be performed based on a pattern to form the recess 1030. In some implementations, another recess may be formed that is defined by the photo resist layer 1028, the dielectric layer 916, and the metal layer 902. In other implementations, the other recess is formed later in the process, such as illustrated in Stage 9.

Stage 8 of FIG. 10C illustrates a state after a third conductive structure 1034 is formed. For example, as part of Stage 8, metal, such as copper, is deposited within the third recess 1030 to form the third conductive structure 1034. In some implementations, after depositing the metal, a planarization operation may be performed to form the third conductive structure 1034.

Stage 9 illustrates a state after a recess 1040 is formed. For example, as part of Stage 9, a photo resist material may be deposited on the photo resist layer 1028, the dielectric layer 916, the first conductive structure 1020, the second dielectric layer 1032, and the third conductive structure 1034. After the photo resist material is deposited, the photo resist material may be patterned, and an etch process may be performed based on a pattern to form the recess 1040 and photo resist layers 1036 and 1038.

Stage 10 illustrates a state after a second conductive structure 1042 is formed. For example, as part of Stage 10, metal, such as copper, may be deposited in the recess 1040. To illustrate, the metal may be deposited to surround the one or more dielectric walls 914 of the dielectric layer 916 to form the second conductive structure 1042. In some implementations, a planarization operation may be performed after the metal is deposited. Additionally, or alternatively, after the metal is deposited, the photo resist layer 1036 or 1038 may be removed. Removal of the photo resist layer 1036, 1038 may reveal a pillar that includes the first conductive structure 1020, the second conductive structure 1042, and the dielectric layer 916 disposed between the second conductive structure 1042 and the first conductive structure 1020 to define an embedded capacitor. The pillar may also include the third conductive structure 1034, and the second dielectric layer 1032 disposed between the first conductive structure 1020 and the third conductive structure 1034 to define another embedded capacitor.

The pillar may be configured to be electrically connected to one or more conductors of a die. For example, the pillar may include or correspond to the pillar 106 of FIGS. 2A-C. The pillar includes the first conductive structure 1020, the second conductive structure 1042, and the dielectric layer 916 disposed between the first conductive structure 1020 and the second conductive structure 1042 to define an embedded capacitor. For example, the first conductive structure 1020, the second conductive structure 1042, and the dielectric layer 916 may include or correspond to the first conductive structure 110, the second conductive structure 112, and the dielectric layer 114, respectively. In some implementations, the pillar includes the third conductive structure 1034 and the second dielectric layer 1032. The third conductive structure 1034 and the second dielectric layer 1032 may include or correspond to the third conductive structure 230 and the second dielectric layer 236, respectively.

In some implementations, the various stages of FIGS. 10A-C may be modified such that a pattern and etch process performed with reference to Stage 7 of FIG. 10B forms the recess 1030 and the other recess may be formed that is defined by the photo resist layer 1028, the dielectric layer 916, and the metal layer 902. Accordingly, at Stage 8 of FIG. 10C, the metal that is deposited may be deposited in the recess 1030 and the other recess to form the third conductive structure 1034 and the second conductive structure 1042. In some implementations, after depositing the metal, a planarization operation may be performed to form the third conductive structure 1034 and the second conductive structure 1042. After formation of the third conductive structure 1034 and the second conductive structure 1042, the photo resist layer 1028 may be removed to reveal the pillar. Accordingly, Stage 9 of FIG. 10C may be omitted.

In some implementations, one or more conductive interconnects (e.g., solder caps) may be formed. For example, the one or more solder caps may include a first solder cap formed on the first conductive structure 1020, a second solder cap formed on the second conductive structure 1042, a third solder cap formed on the third conductive structure 1034, or a combination thereof.

Formation of a device (e.g., a device including a pillar with an embedded capacitor) is complete after Stage 10 of FIG. 10C. The device 940 (e.g., the pillar) may include or correspond to the pillar 106 as described herein at least with reference to FIGS. 2A-C. Although certain Stages are illustrated in FIGS. 10A-C in forming a device that includes a pillar, other processes can be included in the fabrication of the device without departing from the scope of the subject disclosure. For example, fabricating the device that includes the pillar can include one or more patterning operations, one or more plating operations, one or more deposition operations, one or more planarization operations, one or more etching operations, or a combination thereof.

Exemplary Flow Diagram of a Method for Fabricating a Device/Integrated Device Including a Pillar with an Embedded Capacitor

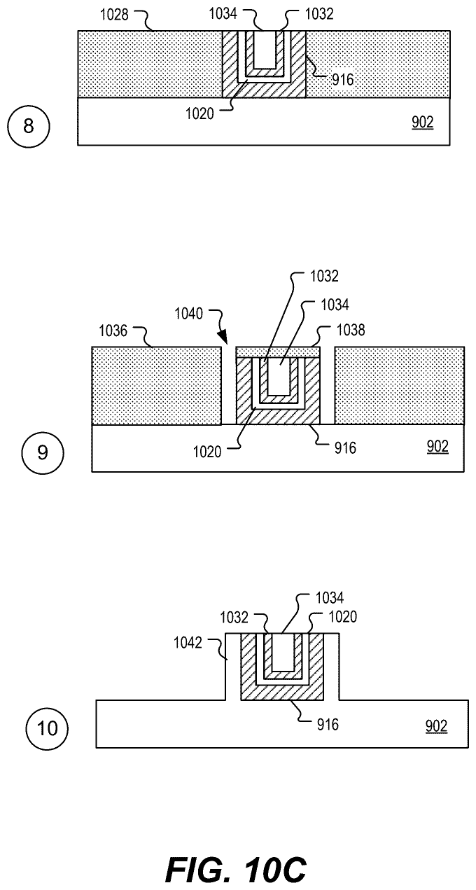

In some implementations, fabricating a device including a pillar with an embedded capacitor includes several processes. FIG. 11 illustrates an exemplary flow diagram of a method 1100 of fabricating an illustrative device that includes a pillar with an embedded capacitor. In a particular aspect, one or more operations of the method 1100 are performed by one or more processors of a fabrication system. In some implementations, operations of the method 1100 may be stored as instructions by a non-transitory computer-readable storage medium, and the instructions may be executable by at least one processor to cause the at least one processor to perform operations of the method 1100. In some implementations, the method 1100 of FIG. 11 may be used to provide or fabricate any of the device 100 of FIGS. 1A-C, the device 400 of FIGS. 4A-B, the device 700 of FIGS. 7A-B, the device 800 of FIGS. 8A-B, or a combination thereof.

It should be noted that the method 1100 of FIG. 11 may combine one or more processes in order to simplify and/or clarify the method for providing or fabricating a device including a pillar with an embedded capacitor. In some implementations, the order of the processes may be changed or modified.

At block 1102, the method 1100 includes forming a pillar electrically connected to one or more conductors of a die. For example, the pillar and the die may include or correspond to the pillar 106 and the die 102, respectively. The pillar includes a first conductive structure, a second conductive structure, and a dielectric layer disposed between the first conductive structure and the second conductive structure to define an embedded capacitor. The first conductive structure may include or correspond to the first conductive structure 110, 930, or 1020. The second conductive structure may include or correspond to the second conductive structure 112, 932, or 1042. The dielectric layer may include or correspond to dielectric layer 114 or 916. In some implementations, the pillar may be formed as described with reference to the various stages of the sequence illustrated in FIG. 9 or the various stages of the sequence illustrated in FIGS. 10A-C.

In some implementations, an end of the first conductive structure is a first distance from the die and an end of the second conductive structure is a second distance from the die. For example, referring to FIG. 7B, the end 751 of the second conductive structure 112 is the second distance 750 from the die 102, and the end 753 of the first conductive structure 110 is the first distance 752 from the die 102. The first distance may be greater than or equal to the second distance.

At block 1104, the method 1100 includes electrically connecting the die to one or more conductors of a substrate using the pillar. For example, the substrate may include or correspond to the substrate 104.

In some implementations, a first thickness (e.g., a thickness 140) of the dielectric layer separates the first conductive structure and the second conductive structure in a direction parallel to a normal of a surface of a substrate. Additionally, or alternatively, a second thickness (e.g., 142) of the dielectric layer separates the first conductive structure and the second conductive structure in a direction parallel to the surface of the substrate. In some implementations, the second thickness may be greater than or equal to the first thickness.

In some implementations, to form the pillar, the method 1100 also includes forming the dielectric layer on a metal layer electrically connected to the one or more conductors of the die. For example, Stage 1 of FIG. 9 illustrates and describes examples of forming the dielectric layer 904 on the metal layer 902 that is electrically connected to one or more conductors of the die 102. As another example, Stage 4 of FIG. 9 illustrates and describes examples of forming the dielectric layer 916 on the metal layer 902 that is electrically connected to one or more conductors of the die 102. The dielectric layer may include one or more dielectric walls defining a first recess, such as the recess 924 of Stage 4 of FIG. 9 or the recess 1004 of Stage 1 of FIG. 10A.

In some implementations, to form the pillar (e.g., after formation of the dielectric layer), the method 1100 may also include depositing metal to form the first conductive structure on the dielectric layer. For example, Stage 5 of FIG. 9 illustrates and describes examples of depositing metal to form the first conductive structure 930 on the dielectric layer 916. To illustrate, the metal may be deposited within the recess 924 to form the first conductive structure 930. As another example, Stage 2 of FIG. 10A and Stage 5 of FIG. 10B illustrate and describe examples of depositing metal to form the first conductive structure 1020 on the dielectric layer 916. The method 1100 may also include forming a conductive interconnect (e.g., a solder cap) on the first conductive structure. For example, Stage 5 of FIG. 9 illustrates and describes examples of forming the solder cap 936. The solder cap of the method 1100 can also include or correspond to solder 116 of FIG. 1.

Additionally, or alternatively, to form the pillar (e.g., after formation of the dielectric layer), the method 1100 may also include depositing metal surrounding the one or more dielectric walls of the dielectric layer to form the second conductive structure. For example, Stage 5 of FIG. 9 illustrates and describes examples of depositing the metal to form the second conductive structure 932. As another example, Stage 10 of FIG. 10C illustrates and describes examples of depositing the metal to form the second conductive structure 1042. The method 1100 may also include forming a second solder cap on the second conductive structure. For example, Stage 5 of FIG. 9 illustrates and describes examples of forming the solder cap 934. The second solder cap of the method 1100 can also include or correspond to solder 116.

In some implementations, the one or more dielectric walls of the dielectric layer define at least two recesses, including the first recess and a second recess. For example, the dielectric layer may include a first dielectric layer (e.g., 114, 916) and a second dielectric layer (e.g., 236, 1032). The one or more walls of the first dielectric layer may define the first recess, and the one or more walls of the second dielectric layer may define the second recess. The method 1100 may include depositing metal within the second recess to form a third conductive structure. For example, Stage 8 of FIG. 10C illustrates and describes examples of formation of the third conductive structure 1034. The third conductive structure may include or correspond to the third conductive structure 230 or the third conductive structure 1034. In some implementations, the method 1110 includes forming a third conductive interconnect (e.g., a solder cap) on the third conductive structure.

In some implementations, to form the pillar (e.g., after formation of the dielectric layer), the method 1100 may include depositing metal within the first recess to form a first portion of the first conductive structure. For example, Stage 2 of FIG. 10A illustrates and describes examples of formation of the first portion 1006 of the first conductive structure 1020. The method 1100 may also include forming a first portion of a second dielectric layer on the first portion of the first conductive structure. For example, Stage 3 of FIG. 10A illustrates and describes examples of formation of the first portion 1012 of the second dielectric layer 1032. The second dielectric layer 1032 may also include or correspond the second dielectric layer 236.

Additionally, the method 1100 may include depositing metal within the first recess on the first portion of the first conductive structure to form a second portion of the first conductive structure. The second portion of the first conductive structure may include one or more walls defining a second recess. For example, Stage 5 of FIG. 10B illustrates and describes examples of depositing metal to form a second portion (e.g., one or more walls) of the first conductive structure 1020. The method 1100 may also include forming a second portion of the second dielectric layer within the second recess and on the first portion of the second dielectric layer. The second portion of the second dielectric layer may include one or more dielectric walls defining a third recess. For example, Stage 7 of FIG. 10B illustrates and describes examples of forming the second portion of the second dielectric layer 1032. The second portion of the second dielectric layer 1032 includes the one or more dielectric walls that define the recess 1030.

The method 1100 may include depositing metal within the third recess to form a third conductive structure. For example, Stage 8 of FIG. 10C illustrates and describes examples of formation of the third conductive structure 1034. The third conductive structure of the method 1100 can include or correspond to the third conductive structure 230. The method 1100 may include depositing metal surrounding the one or more dielectric walls of the first dielectric layer to form the second conductive structure. For example, Stage 10 of FIG. 10C illustrates and describes examples of depositing metal surrounding one or more dielectric walls 914 of the dielectric layer 916 to form the second conductive structure 1042. The second conductive structure of the method 1100 can include or correspond to the conductive structure 112. The method 1100 can also including forming one or more conductive interconnects (e.g., solder caps) on the first conductive structure, the second conductive structure, or the third conductive structure. For example, the method 1100 can include forming a first solder cap on the first conductive structure, forming a second solder cap on the second conductive structure, or forming a third solder cap on the third conductive structure.

### Exemplary Electronic Devices

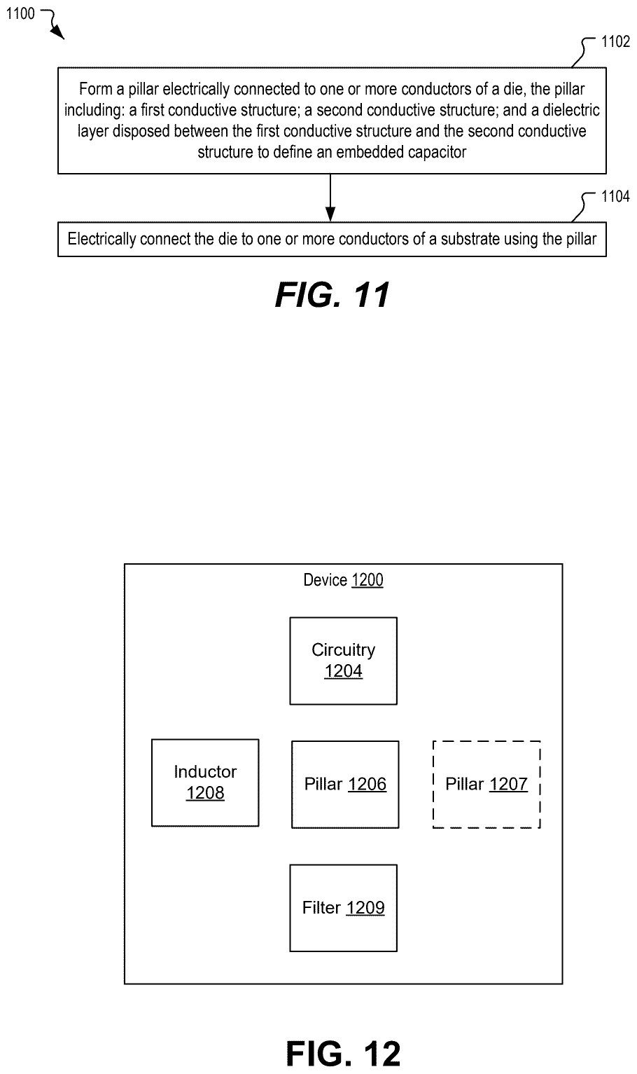

FIG. 12 illustrates a schematic diagram of an exemplary device 1200 that includes the pillar 106 with an embedded capacitor. The device 1200 may include or correspond to the device 100, 400, 700, or 800. The device 1200 includes circuitry 1204, a pillar 1206, an inductor 1208, and a filter 1209. The device 1200, may optionally (as indicated by a dashed box) include a pillar 1207. In some implementations, the device 1200 includes or corresponds to a matching network for a power amplifier, such as a low band (less than 1 GHz) power amplifier or a mid band (1 GHz-6 Gz) power amplifier, as illustrative, non-limiting examples.

The circuitry 1204 may include or correspond to the integrated circuitry 122 of FIG. 1. In some implementations, the circuitry 1204 includes power amplifier circuitry. For example, the power amplifier circuitry may include a transistor, such as the transistor 802. A collector of the transistor may be electrically coupled to the pillar 1206.

The pillar 1206 may include or correspond to the pillar 106 of FIG. 1A-C, 2A-C, 3A-C, 4A-B, 5A-B, 6A-B, or 7A-B. The pillar 1206 may be electrically coupled the circuitry 1204, the inductor 1208, the filter 1209, or a combination thereof. In some implementations, the pillar 1206 may include a first conductive structure (e.g., the first conductive structure 110), a second conductive structure (e.g., the second conductive structure 112), a dielectric layer (e.g., dielectric layer 114), or a combination thereof. The second conductive structure may be electrically connected to a collector of the transistor of the circuitry 1204. Additionally, or alternatively, the second conductive structure can be electrically connected to a collector of a direct current circuit path, such as the DC signal path 146. For example, the direct current circuit path may include the transistor of the circuitry 1204. In some such implementations, the first conductive structure is electrically connected to an alternating current circuit path (e.g., the capacitively coupled signal path 144) of the filter 1209.

The inductor 1208 may include or correspond to the inductor 804 of FIGS. 8A-B. In some implementations, the inductor 1208 is or includes a choke inductor. The inductor may electrically be coupled to a collector of the transistor of the circuitry 1204 though the first conductive structure of the pillar 1206.

The filter 1009 may include one or more inductors, a capacitor, or a combination thereof. For example, the one or more inductors may include or correspond to the inductors 804, 806, or 808. The capacitor may include or correspond to the capacitor 810, such as a polarized fixed capacitor.

In some implementations, the device 1200 includes a die, a substrate, or a combination thereof. For example, the die may include or correspond to the die 102, and the substrate may include or correspond to the substrate 104. In some implementations, the die may include the circuitry 1204. Additionally, or alternatively, the substrate may include inductor 1208, the filter 1209, or a combination thereof. The pillar 1206 may be positioned between the die and the substrate and be coupled or electrically coupled to the die, the substrate, or a combination thereof. In some implementations, the pillar 1206 is considered part of the die, while in other implementations, the pillar is considered part of the substrate.

The pillar 1207 may include or correspond to the pillar 106 of FIG. 1A-C, 2A-C, 3A-C, 4A-B, 5A-B, 6A-B, or 7A-B, or the one or more additional pillars 120. The pillar 1207 may have the same configuration (e.g., structural configuration) as the pillar 1206 or may have a different configuration as compared to the pillar 1206. For example, both of the pillars 1206 and 1207 may be configured as described with reference to the pillar 106 of FIGS. 1A-C. As another example, the pillar 1206 may be configured as described with reference to the pillar 106 of FIGS. 1A-C, and the pillar 1207 may be configured as described with reference to the pillar 106 of FIGS. 2A-C.

FIG. 13 illustrates various electronic devices that may include or be integrated with any of the pillar 106 or the device 100, 400, 700, or 800, 1200 (that includes the pillar 106 with an embedded capacitor). For example, a mobile phone device 1302, a laptop computer device 1304, a fixed location terminal device 1306, a wearable device 1308, or a vehicle 1310 (e.g., an automobile or an aerial device) may include a device 1300. The device 1300 can include, for example, any of the device 100, 400, 700, or 800, 1200, and/or any other integrated device that includes a pillar with an embedded capacitor described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-13 may be rearranged and/or combined into a single component, process, feature or function or embodied in several components, processes, or functions. Additional elements, components, processes, and/or functions may also be added without departing from the disclosure. It should also be noted FIGS. 1A-13 and its corresponding description in the present disclosure is not limited to dies and/or ICs. In some implementations, FIGS. 1A-13 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third”, and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating”, or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a die, a substrate, and a pillar having an embedded capacitor. The pillar is electrically connected to one or more conductors of the die and to one or more conductors of the substrate. The pillar includes a first conductive structure; a second conductive structure; and a dielectric layer disposed between the first conductive structure and the second conductive structure to define the embedded capacitor.

Example 2 includes the device of Example 1, wherein the pillar defines at least two conductive paths between the one or more conductors of the substrate and the one or more conductors of the die, the at least two conductive paths including a direct-current path and a capacitively-coupled path.

Example 3 includes the device of Example 2, wherein a portion of the second conductive structure is common to the direct-current path and the capacitively-coupled path.

Example 4 includes the device of any of Examples 1 to 3, wherein an end of the first conductive structure is a first distance from the die and an end of the second conductive structure is a second distance from the die, wherein the first distance is greater than the second distance.

Example 5 includes the device of any of Examples 1 to 4, wherein the first conductive structure is nested within the second conductive structure.

Example 6 includes the device of any of Examples 1 to 5, wherein the pillar further includes a third conductive structure and a second dielectric layer defining a second embedded capacitor.

Example 7 includes the device of Example 6, wherein the third conductive structure is nested within the first conductive structure.

Example 8 includes the device of Example 6 or Example 7, wherein the embedded capacitor and the second embedded capacitor are coupled electrically in series with one another between the one or more conductors of the die and the one or more conductors of the substrate.

Example 9 includes the device of any of Examples 1 to 5, wherein the pillar further includes a third conductive structure and a second dielectric layer defining a second embedded capacitor, wherein the third conductive structure is disposed side-by-side with the first conductive structure.

Example 10 includes the device of Example 9, wherein the embedded capacitor and the second embedded capacitor are coupled electrically in parallel with one another between the one or more conductors of the die and the one or more conductors of the substrate.

Example 11 includes the device of any of Examples 1 to 10, wherein the first conductive structure and the second conductive structure include copper, and the dielectric layer includes silicon nitride.

Example 12 includes the device of any of Examples 1 to 11 and further includes a plurality of additional pillars electrically connecting additional conductors of the die to additional conductors of the substrate, wherein the pillar has a first pillar height substantially equal to a second pillar height of the one or more additional pillars.

Example 13 includes the device of any of Examples 1 to 12, wherein a first thickness of the dielectric layer separates the first conductive structure and the second conductive structure in a direction parallel to a normal of a surface of the substrate, and wherein a second thickness of the dielectric layer separates the first conductive structure and the second conductive structure in a direction parallel to the surface of the substrate, and wherein the second thickness is different than the first thickness.

Example 14 includes the device of any of Examples 1 to 13, wherein the die includes power amplifier circuitry and the substrate includes conductors arranged to form an inductor of a filter, and wherein: the second conductive structure is electrically connected to a collector of a transistor of the power amplifier circuitry of the die; the second conductive structure is electrically connected to a collector of a direct current circuit path of the substrate; and the first conductive structure is electrically connected to an alternating current circuit path of the filter.

According to Example 15, a method of fabrication includes forming a pillar electrically connected to one or more conductors of a die. The pillar includes a first conductive structure, a second conductive structure, and a dielectric layer disposed between the first conductive structure and the second conductive structure to define an embedded capacitor. The method also includes electrically connecting the die to one or more conductors of a substrate using the pillar.

Example 16 includes the method of Example 15, wherein forming the pillar includes: forming the dielectric layer on a metal layer electrically connected to the one or more conductors of the die; depositing metal to form the first conductive structure on the dielectric layer; and forming a solder cap on the first conductive structure.

Example 17 includes the method of Example 15, wherein forming the pillar includes: forming the dielectric layer on a metal layer electrically connected to the one or more conductors of the die, where the dielectric layer includes one or more walls defining a first recess. The method includes depositing metal surrounding the one or more walls of the dielectric layer to form the second conductive structure; depositing metal within the first recess to form the first conductive structure; forming a first solder cap on the first conductive structure; and forming a second solder cap on the second conductive structure.

Example 18 includes the method of Example 17, wherein the one or more walls of the dielectric layer define at least two recesses, including the first recess and a second recess, and the method further includes: depositing metal within the second recess to form a third conductive structure; and forming a third solder cap on the third conductive structure.

Example 19 includes the method of Example 15, wherein forming the pillar includes: forming the dielectric layer on a metal layer electrically connected to the one or more conductors of the die, wherein the dielectric layer includes one or more walls defining a first recess; depositing metal within the first recess to form a first portion of the first conductive structure; forming a first portion of a second dielectric layer on the first portion of the first conductive structure; depositing metal within the first recess on the first portion of the first conductive structure to form a second portion of the first conductive structure, the second portion of the first conductive structure including one or more walls defining a second recess; forming a second portion of the second dielectric layer within the second recess and on the first portion of the second dielectric layer, the second portion of the second dielectric layer including one or more walls defining a third recess; depositing metal within the third recess to form a third conductive structure; depositing metal surrounding the one or more walls of the first dielectric layer to form the second conductive structure; forming a first solder cap on the first conductive structure; forming a second solder cap on the second conductive structure; and forming a third solder cap on the third conductive structure.

Example 20 includes the method of any of Examples 15 to 19, wherein a first thickness of the dielectric layer separates the first conductive structure and the second conductive structure in a direction parallel to a normal of a surface of the substrate, and wherein a second thickness of the dielectric layer separates the first conductive structure and the second conductive structure in a direction parallel to the surface of the substrate, and wherein the second thickness is greater than the first thickness.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a die;
a substrate; and
a pillar having an embedded capacitor, the pillar electrically connected to one or more conductors of the die and to one or more conductors of the substrate, the pillar including:
a first conductive structure;
a second conductive structure; and
a dielectric layer disposed between the first conductive structure and the second conductive structure to define the embedded capacitor.

2. The device of claim 1, wherein the pillar defines at least two conductive paths between the one or more conductors of substrate and the one or more conductors of the die, the at least two conductive paths including a direct-current path and a capacitively-coupled path.

3. The device of claim 2, wherein a portion of the second conductive structure is common to the direct-current path and the capacitively-coupled path.

4. The device of claim 1, wherein an end of the first conductive structure is a first distance from the die and an end of the second conductive structure is a second distance from the die, wherein the first distance is greater than the second distance.

5. The device of claim 1, wherein the first conductive structure is nested within the second conductive structure.

6. The device of claim 1, wherein the pillar further includes a third conductive structure and a second dielectric layer defining a second embedded capacitor.

7. The device of claim 6, wherein the third conductive structure is nested within the first conductive structure.

8. The device of claim 6, wherein the embedded capacitor and the second embedded capacitor are coupled electrically in series with one another between the one or more conductors of the die and the one or more conductors of the substrate.

9. The device of claim 1, wherein:
the pillar further includes a third conductive structure and a second dielectric layer defining a second embedded capacitor, and
the third conductive structure is disposed side-by-side with the first conductive structure.

10. The device of claim 9, wherein the embedded capacitor and the second embedded capacitor are coupled electrically in parallel with one another between the one or more conductors of the die and the one or more conductors of the substrate.

11. The device of claim 1, wherein the first conductive structure and the second conductive structure include copper, and the dielectric layer includes silicon nitride.

12. The device of claim 1, further comprising:
a plurality of additional pillars electrically connecting additional conductors of the die to additional conductors of the substrate, and
wherein the pillar has a first pillar height substantially equal to a second pillar height of the one or more additional pillars.

13. The device of claim 1, wherein:
a first thickness of the dielectric layer separates the first conductive structure and the second conductive structure in a direction parallel to a normal of a surface of the substrate,
a second thickness of the dielectric layer separates the first conductive structure and the second conductive structure in a direction parallel to the surface of the substrate, and
the second thickness is different than the first thickness.

14. The device of claim 1, wherein
the die includes power amplifier circuitry and the substrate includes conductors arranged to form an inductor of a filter,
the second conductive structure is electrically connected to a collector of a transistor of the power amplifier circuitry of the die;
the second conductive structure is electrically connected to a collector of a direct current circuit path of the substrate; and
the first conductive structure is electrically connected to an alternating current circuit path of the filter.

15. A method of fabrication comprising:
forming a pillar electrically connected to one or more conductors of a die, the pillar including:
a first conductive structure;
a second conductive structure; and
a dielectric layer disposed between the first conductive structure and the second conductive structure to define an embedded capacitor; and
electrically connecting the die to one or more conductors of a substrate using the pillar.

16. The method of claim 15, wherein forming the pillar includes:
forming the dielectric layer on a metal layer electrically connected to the one or more conductors of the die;
depositing metal to form the first conductive structure on the dielectric layer; and
forming a solder cap on the first conductive structure.

17. The method of claim 15, wherein forming the pillar includes:
forming the dielectric layer on a metal layer electrically connected to the one or more conductors of the die, wherein the dielectric layer includes one or more walls defining a first recess;
depositing metal surrounding the one or more walls of the dielectric layer to form the second conductive structure;
depositing metal within the first recess to form the first conductive structure;
forming a first solder cap on the first conductive structure; and
forming a second solder cap on the second conductive structure.

18. The method of claim 17, wherein:
the one or more walls of the dielectric layer define at least two recesses, including the first recess and a second recess, and
the method further comprises:
depositing metal within the second recess to form a third conductive structure; and
forming a third solder cap on the third conductive structure.

19. The method of claim 15, wherein forming the pillar includes:
forming the dielectric layer on a metal layer electrically connected to the one or more conductors of the die, wherein the dielectric layer includes one or more walls defining a first recess;
depositing metal within the first recess to form a first portion of the first conductive structure;
forming a first portion of a second dielectric layer on the first portion of the first conductive structure;
depositing metal within the first recess on the first portion of the first conductive structure to form a second portion of the first conductive structure, the second portion of the first conductive structure including one or more walls defining a second recess;
forming a second portion of the second dielectric layer within the second recess and on the first portion of the second dielectric layer, the second portion of the second dielectric layer including one or more walls defining a third recess;
depositing metal within the third recess to form a third conductive structure;
depositing metal surrounding the one or more walls of the first dielectric layer to form the second conductive structure;
forming a first solder cap on the first conductive structure;
forming a second solder cap on the second conductive structure; and
forming a third solder cap on the third conductive structure.

20. The method of claim 15, wherein:
a first thickness of the dielectric layer separates the first conductive structure and the second conductive structure in a direction parallel to a normal of a surface of the substrate,
a second thickness of the dielectric layer separates the first conductive structure and the second conductive structure in a direction parallel to the surface of the substrate, and
the second thickness is greater than the first thickness.
